(19) United States
(12) Patent Application Publication
(10) Pub. No.: US 2025/0146940 A1
(43) Pub. Date: May 8, 2025

(54) INSPECTION METHOD OF LIGHT-EMITTING ELEMENT

(71) Applicant: Japan Display Inc., Tokyo (JP)

(72) Inventor: Masanobu IKEDA, Tokyo (JP)

(73) Assignee: Japan Display Inc., Tokyo (JP)

(21) Appl. No.: 19/014,377

(22) Filed: Jan. 9, 2025

Related U.S. Application Data
(63) Continuation of application No. PCT/JP2023/022261, filed on Jun. 15, 2023.

(30) Foreign Application Priority Data
Sep. 6, 2022 (JP) 2022-141167

(51) Int. Cl. G01N 21/64; G01N 21/66

(52) U.S. Cl. CPC G01N 21/6489; G01N 21/66

(57) ABSTRACT

Disclosed is a method for inspecting a light-emitting element, the method including: forming a buffer layer over an amorphous substrate; forming, over the buffer layer, an n-type cladding layer, an emission layer, and a p-type cladding layer each including an inorganic semiconductor to form a plurality of semiconductor layers arranged in a matrix form having a plurality of rows and a plurality of columns; forming an anode and a cathode over each of the plurality of semiconductor layers to form a plurality of light-emitting elements; and acquiring at least one of a photoluminescence property or an electroluminescence property of the plurality of light-emitting elements using a first detector and a second detector. The buffer layer has a function to promote crystallization of the semiconductor layers. The photoluminescence property is acquired before forming the anode and the cathode. The electroluminescence property is acquired after forming the anode and the cathode.

### CROSS-REFERENCE TO RELATED APPLICATIONS

This application is a Continuation of International Patent Application No. PCT/JP2023/022261, filed on Jun. 15, 2023, which claims the benefit of priority to Japanese Patent Application No. 2022-141167, filed on Sep. 6, 2022, the entire contents of which are incorporated herein by reference.

### FIELD

An embodiment of the present invention relates to a method for inspecting a light-emitting element. For example, an embodiment of the present invention relates to a method for inspecting a plurality of inorganic light-emitting elements disposed on a large amorphous substrate.

### BACKGROUND

In recent years, inorganic light-emitting diodes (LEDs) have been widely used as light-emitting elements, and LEDs are used not only in lighting devices but also in display devices. In the field of display devices, LEDs have been conventionally used as backlights for liquid crystal displays (LCDs). However, in recent years, display devices in which LEDs are provided in pixels arranged in a matrix shape have been developed. LEDs can be fabricated by stacking a plurality of layers including an inorganic compound of Group 12, 13, and 15 elements or the like, which are exemplified by gallium, indium, arsenic, zinc, and selenium, over a wide-gap semiconductor substrate or an amorphous glass substrate, followed by forming a pair of electrodes thereover (see, International patent publication No. 2016/121628, Japanese laid-open patent publication No. 2015-010834, International patent publication No. 2018/042792, and Japanese Patent No. 6723484).

### SUMMARY

An embodiment of the present invention is a method for inspecting a light-emitting element. This method includes: forming a buffer layer over an amorphous substrate; forming, over the buffer layer, an n-type cladding layer, an emission layer, and a p-type cladding layer each including an inorganic semiconductor to form a plurality of semiconductor layers arranged in a matrix form having a plurality of rows and a plurality of columns; forming an anode and a cathode over each of the plurality of semiconductor layers to form a plurality of light-emitting elements; and acquiring at least one of a photoluminescence property or an electroluminescence property of the plurality of light-emitting elements using a first detector and a second detector. The buffer layer has a function to promote crystallization of the semiconductor layers. The photoluminescence property is acquired before forming the anode and the cathode. The electroluminescence property is acquired after forming the anode and the cathode.

### BRIEF DESCRIPTION OF DRAWINGS

FIG. 1 is a flowchart explaining an inspecting method of a light-emitting element according to an embodiment of the present invention.

FIG. 2 is a flowchart explaining an inspecting method of a light-emitting element according to an embodiment of the present invention.

FIG. 3 is a flowchart explaining an inspecting method of a light-emitting element according to an embodiment of the present invention.

FIG. 4A is a schematic top view explaining an inspecting method of a light-emitting element according to an embodiment of the present invention.

FIG. 4B is a schematic cross-sectional view explaining an inspecting method of a light-emitting element according to an embodiment of the present invention.

FIG. 5A is a schematic top view explaining an inspecting method of a light-emitting element according to an embodiment of the present invention.

FIG. 5B is a schematic top view explaining an inspecting method of a light-emitting element according to an embodiment of the present invention.

FIG. 6A is a schematic side view explaining an inspecting method of a light-emitting element according to an embodiment of the present invention.

FIG. 6B is a schematic top view explaining an inspecting method of a light-emitting element according to an embodiment of the present invention.

FIG. 7A is a schematic side view explaining an inspecting method of a light-emitting element according to an embodiment of the present invention.

FIG. 7B is a schematic top view explaining an inspecting method of a light-emitting element according to an embodiment of the present invention.

FIG. 8A is a schematic top view explaining an inspecting method of a light-emitting element according to an embodiment of the present invention.

FIG. 8B is a schematic top view of an inspection substrate used in an inspecting method of a light-emitting element according to an embodiment of the present invention.

FIG. 9A is a schematic top view explaining an inspecting method of a light-emitting element according to an embodiment of the present invention.

FIG. 9B is a schematic cross-sectional view explaining an inspecting method of a light-emitting element according to an embodiment of the present invention.

FIG. 10A is a schematic top view explaining an inspecting method of a light-emitting element according to an embodiment of the present invention.

FIG. 10B is a schematic top view explaining an inspecting method of a light-emitting element according to an embodiment of the present invention.

FIG. 11A is a schematic top view explaining an inspecting method of a light-emitting element according to an embodiment of the present invention.

FIG. 11B is a schematic cross-sectional view explaining an inspecting method of a light-emitting element according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented. When a portion of a structure is shown, a lower-case letter of the alphabet may be added.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

Hereinafter, an inspecting method of a plurality of light-emitting elements according to an embodiment of the present invention (hereinafter simply referred to as the inspecting method) and a manufacturing method of a light-emitting device including the inspecting method are described. The light-emitting element which is an object of the inspecting method is a LED including a semiconductor layer, which is a laminate of a plurality of layers each containing an inorganic semiconductor, and a pair of electrodes (anode and cathode) electrically connected to the semiconductor layer. In this inspecting method, a plurality of semiconductor layers or a plurality of light-emitting elements is formed over an amorphous substrate, and one or both photoluminescence (PL) and electroluminescence (EL) from the semiconductor layers are utilized.

### 1. Outline

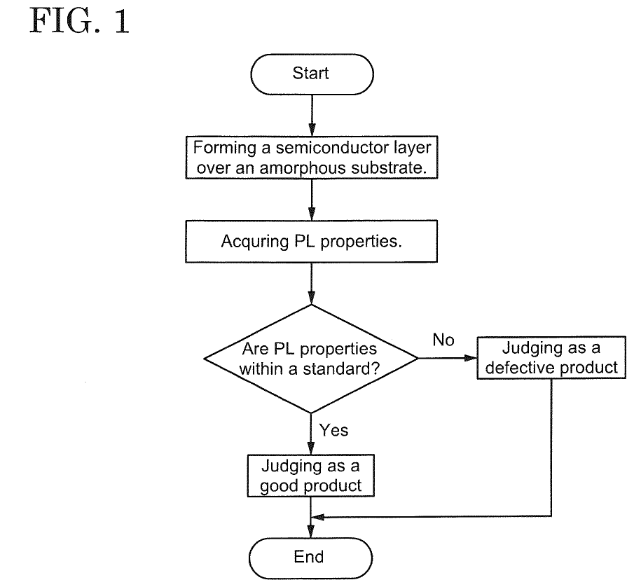

In the inspecting method utilizing photoluminescence, a plurality of semiconductor layers is formed over an amorphous substrate as shown in the flowchart in FIG. 1. After that, the plurality of semiconductor layers is irradiated with light to acquire emission properties, that is, the photoluminescence properties, obtained from the semiconductor layers. The photoluminescence properties can be acquired on the basis of, for example, a photoluminescence spectrum, and the acquired properties of the spectrum (e.g., intensity, peak wavelength, and shape of the spectrum) are evaluated. If these properties are within a standard, the semiconductor layer is judged to be a good product, while, if these properties are outside the standard, the semiconductor layer is judged to be a defective product. It is not always necessary to acquire the photoluminescence properties from the photoluminescence spectrum, and the photoluminescence properties may be acquired from, for example, the intensity (luminance) or chromaticity of emission or the shape or area of the emission region obtained from the semiconductor layer.

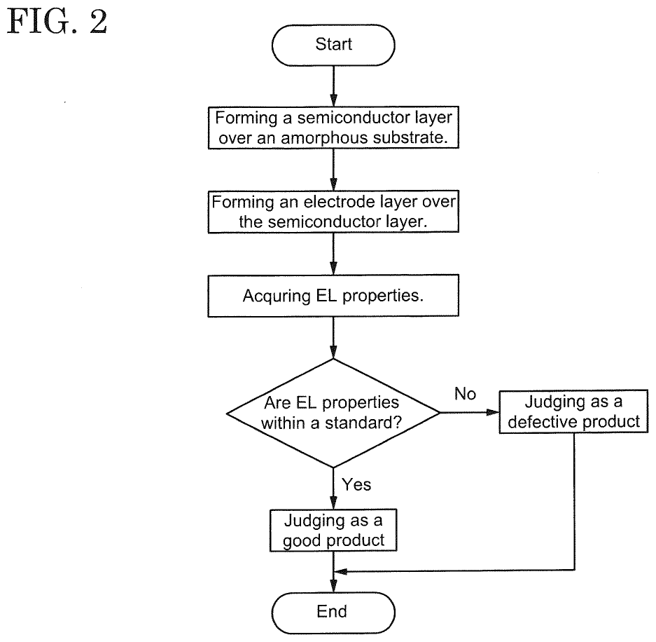

In the inspecting method utilizing electroluminescence, a plurality of semiconductor layers is formed over an amorphous substrate, and then an anode and a cathode are formed over each of the plurality of semiconductor layers to form a plurality of light-emitting elements as shown in the flowchart in FIG. 2. After that, electric power is supplied to the plurality of light-emitting elements to acquire the emission properties, that is, electroluminescence properties, obtained from the semiconductor layer. Similar to the photoluminescence properties, the electroluminescence properties can be acquired on the basis of the electroluminescence spectrum, and the acquired properties of the spectrum are evaluated. If these properties are within a standard, the light-emitting element is judged to be a good product, while, if these properties are outside the standard, the light-emitting element is judged to be a defective product. Alternatively, the intensity (luminance) or chromaticity of the electroluminescence obtained from the semiconductor layer or the shape or area of the emission region may be utilized as the electroluminescence properties.

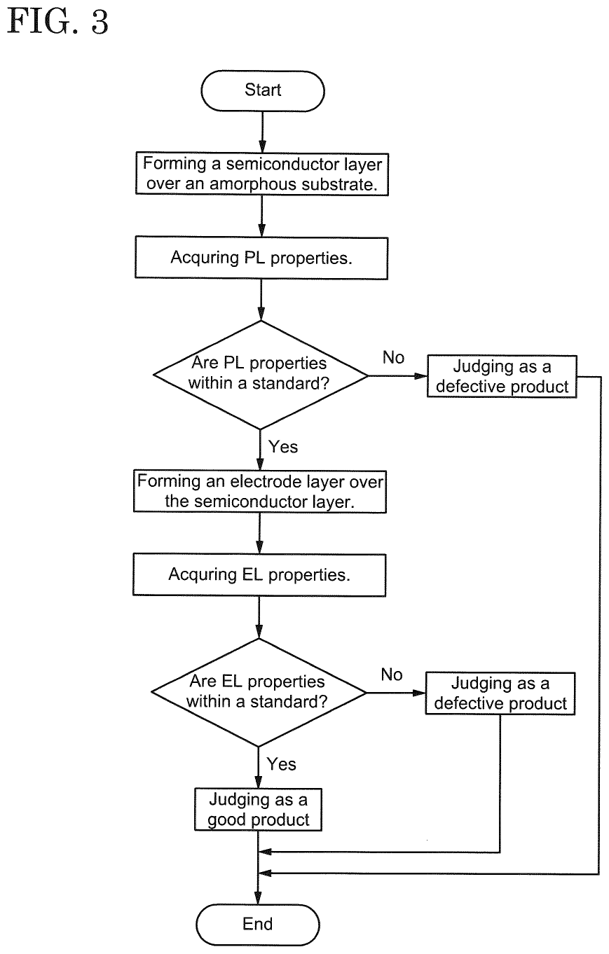

In the inspecting method using both photoluminescence and electroluminescence, a plurality of semiconductor layers is formed over an amorphous substrate as shown in the flowchart in FIG. 3. The photoluminescence properties are then evaluated as described above. If the photoluminescence property is outside of a standard, the semiconductor layer is judged to be a defective product. On the other hand, the semiconductor layers having the photoluminescence properties within the standard are further subjected to the inspection utilizing electroluminescence. Namely, after forming an anode and a cathode over each of the plurality of semiconductor layers to form a plurality of light-emitting elements, electric power is supplied to the plurality of light-emitting elements as described above, and the electroluminescence properties obtained from the semiconductor layers are evaluated. If the electroluminescence properties are within a standard, the light-emitting element is judged to be a good product, while, if they are outside the standard, the light-emitting element is judged to be a defective product. Therefore, in the inspecting method utilizing both photoluminescence and electroluminescence, the light-emitting element is judged to be a good product only when both the photoluminescence properties and the electroluminescence properties are within the standard. Conversely, if at least one of the photoluminescence properties and the electroluminescence properties are outside the standard, the light-emitting element is judged to be a defective product. Hereinafter, the details of this inspecting method are described.

### 2. Light-Emitting Element

### (1) Substrate

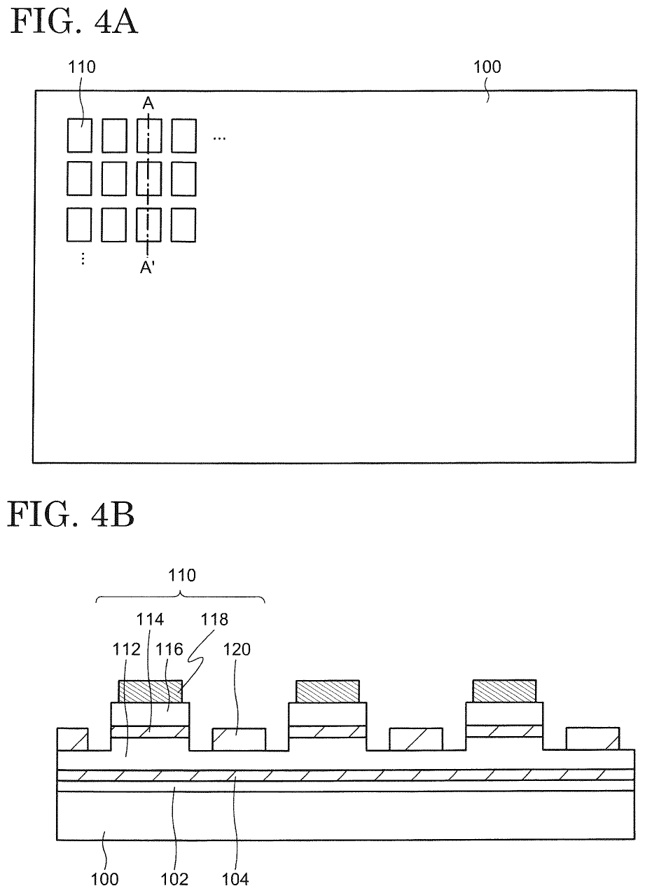

As shown in the schematic top view in FIG. 4A, the light-emitting element 110, a target of the inspecting method, is provided over an amorphous substrate 100. The substrate 100 is, for example, a glass substrate. The substrate 100 may be thick enough to be flexible. Preferably, a substrate with a low coefficient of thermal expansion, a high strain point, and a high surface flatness is used as the substrate 100. For example, the substrate 100 is preferred to have a coefficient of thermal expansion lower than 50×10⁻⁷/° C. and a strain point equal to or higher than 600° C. The content of alkali metals such as sodium in the substrate 100 is preferred to be equal to or less than 0.1%. Therefore, when the substrate 100 is a glass substrate, a glass substrate formed of aluminoborosilicate glass or aluminosilicate glass may be used, for example. When the electroluminescence properties are acquired through the substrate 100 in the inspecting method using electroluminescence, the substrate 100 is preferably configured to transmit visible light.

There is no restriction on the shape of the substrate 100, and the shape is preferred to be a quadrangle such as a square and a rectangle. There is also no restriction on the size of substrate 100, and the size may be for example, a 600 mm×720 mm size called 3.5 generation glass, a 730 mm×920 mm size called 4.5 Generation glass, a 1500 mm×1850 mm size called sixth generation glass, or a larger size than these sizes. Since the use of a large substrate 100 makes it possible to inspect a large number of light-emitting elements, low-cost and efficient inspection can be carried out.

### (2) Structure of Light-Emitting Element

The light-emitting elements 110 are arranged in a matrix shape with a plurality of rows and a plurality of columns (see FIG. 4A). A schematic view of a cross section along the chain line A-A′ intersecting three consecutive light-emitting elements 110 is shown in FIG. 4B. As shown in FIG. 4B, a buffer layer 104 is provided over the substrate 100. The buffer layer 104 is provided through a barrier layer 102 or in direct contact with the substrate 100. Over the buffer layer 104 are provided an n-type cladding layer 112, an emission layer 114 over the n-type cladding layer 112, a p-type cladding layer 116 over the emission layer 114, and an anode 118 and a cathode 120 electrically connected to the p-type cladding layer 116 and n-type cladding layer 112, respectively. A stack of the n-type cladding layer 112, the emission layer 114, and the p-type cladding layer 116 is the semiconductor layer, and the light-emitting element 110 is composed of this semiconductor layer, the anode 118, and the cathode 120. The buffer layer 104 and the n-type cladding layer 112 may be formed to be continuous between adjacent light-emitting elements 110. In other words, the buffer layer 104 and the n-type cladding layer 112 may be provided over the substrate 100 so as to be shared by the plurality of light-emitting elements 110.

a. Barrier Layer

The barrier layer 102 is a film preventing impurities such as sodium ions contained in the substrate 100 from diffusing toward the light-emitting element 110 side. The barrier layer 102 is, for example, a laminate of one or a plurality of films containing a silicon-containing inorganic compound such as silicon oxide and silicon nitride and may be formed by a sputtering method or a chemical vapor deposition (CVD) method.

b. Buffer Layer

The buffer layer 104 is a film functioning to promote crystallization of the semiconductor layer stacked thereover and may include an insulating material or a conductive material having a hexagonal close-packed structure, a face-centered cubic structure, or a structure equivalent thereto. Here, the structure equivalent to the hexagonal close-packed structure or the face-centered cubic structure includes a crystal structure in which the c-axis is not orthogonal to the a-axis and b-axis. Therefore, in this structure, the buffer layer 104 is oriented in the (0001) direction with respect to the substrate 100, that is, the c-axis direction. The buffer layer 104 having the face-centered cubic structure or the structure equivalent thereto is oriented in the (111) direction with respect to the substrate 100. Therefore, the c-axis of the buffer layer 104 is oriented in a direction perpendicular or substantially perpendicular to the surface over which the buffer layer 104 is provided. As described below, an inorganic semiconductor such as a gallium-nitride based material is included in the semiconductor layer, and such an inorganic semiconductor has been known to take a hexagonal close-packed structure and undergo crystal growth in the c-axis direction to minimize its surface energy. Therefore, the formation of the semiconductor layer over the buffer layer 104 promotes crystal growth of the semiconductor layer in the c-axis direction. As a result, the crystallinity of the semiconductor layer is improved.

The buffer layer 104 with such a structure may include a metal nitride such as aluminum nitride and titanium nitride, a metal oxide such as zinc oxide, aluminum oxide, lithium niobate (LiNbO), BiLaTiO, SrFeO, BiFeO, BaFeO, ZnFeO, and PMnN-PZT, a basic calcium phosphate (bio-apatite), or the like. The use of such materials allows the formation of the insulating buffer layer 104. Alternatively, the buffer layer 104 may include a metal such as titanium, aluminum, silver, nickel, copper, strontium, rhodium, palladium, iridium, platinum, and gold.

c. Semiconductor Layer

The n-type cladding layer 112, the emission layer 114, and the p-type cladding layer 116 structuring the semiconductor layers are configured so that visible light is emitted by recombination of holes and electrons respectively injected from the anode 118 and cathode 120. The n-type cladding layer 112, the emission layer 114, and the p-type cladding layer 116 may each have a monolayer structure or a stacked-layer structure in which a plurality of layers is stacked. Although the n-type cladding layer 112, the emission layer 114, and the p-type cladding layer 116 are stacked in this order from the substrate 100 side in the example shown in FIG. 4B, the semiconductor layer may be configured in the reverse order. In this case, the p-type cladding layer 116 may be formed to be shared by the plurality of light-emitting elements 110.

The n-type cladding layer 112, the emission layer 114, and the p-type cladding layer 116 each contain an inorganic semiconductor. The inorganic semiconductors include compounds containing Group 13 and Group 15 elements. More specifically, semiconductors containing aluminum, gallium, and/or indium as well as nitrogen, phosphorus, and/or arsenic are represented, and gallium-based materials are typically represented. For example, gallium nitride-based materials such as gallium nitride (GaN), aluminum gallium nitride (AlGaN), and indium gallium nitride (InGaN) and gallium phosphide-based materials such as gallium phosphide (GaP) and aluminum indium gallium phosphorus (AlGaInP) are represented as the gallium-based materials. Dopants may further be included in the n-type cladding layer 112 and the p-type cladding layer 116. The dopants include elements such as silicon, germanium, magnesium, zinc, cadmium, and beryllium. The addition of these elements enables valence electron control in each layer, by which not only can the intrinsic properties (i-type) be maintained but also the band-gap control and the addition of p-type or n-type conductivity can be achieved. The p-type cladding layer 116 is provided with p-type conductivity, while the n-type cladding layer 112 is provided with n-type conductivity. For example, p-type aluminum gallium nitride and/or p-type gallium nitride may be used for the p-type cladding layer 116, and n-type gallium nitride and/or n-type aluminum gallium nitride may be used for the n-type cladding layer 112.

The emission layer 114 may be a single-layer structure of indium gallium nitride or may have a quantum well structure, for example. The quantum well structure is a structure in which a plurality of thin layers with different band gaps and thicknesses ranging from approximately 1 to 5 nm is alternately stacked and is exemplified by alternately stacked layers of indium gallium nitride and gallium nitride, alternately stacked layers of gallium indium arsenide phosphide (GaInAsP) and indium phosphide (InP), alternately stacked layers of indium aluminum indium arsenide (AlInAs) and indium gallium arsenide (InGaAs), and the like.

d. Anode and Cathode

The anode 118 and the cathode 120 respectively inject holes and electrons into the p-type cladding layer 116 and n-type cladding layer 112. As the anode 118, a thin film of a metal such as palladium and gold or an alloy of these metals may be used, for example. As the cathode, a metal such as silver and indium or an alloy of these metals may be used. The light-emitting element 110 may be configured so that the emission obtained in the emission layer 114 is extracted from the anode 118 side or conversely from the substrate 100 side. In the former case, the anode 118 is provided so as not to entirely cover the p-type cladding layer 116. In other words, at least a portion of the p-type cladding layer 116 in contact with the anode 118 is exposed from the anode 118.

### 3. Inspecting Method for Light-Emitting Element

### (1) Formation of Alignment Mark

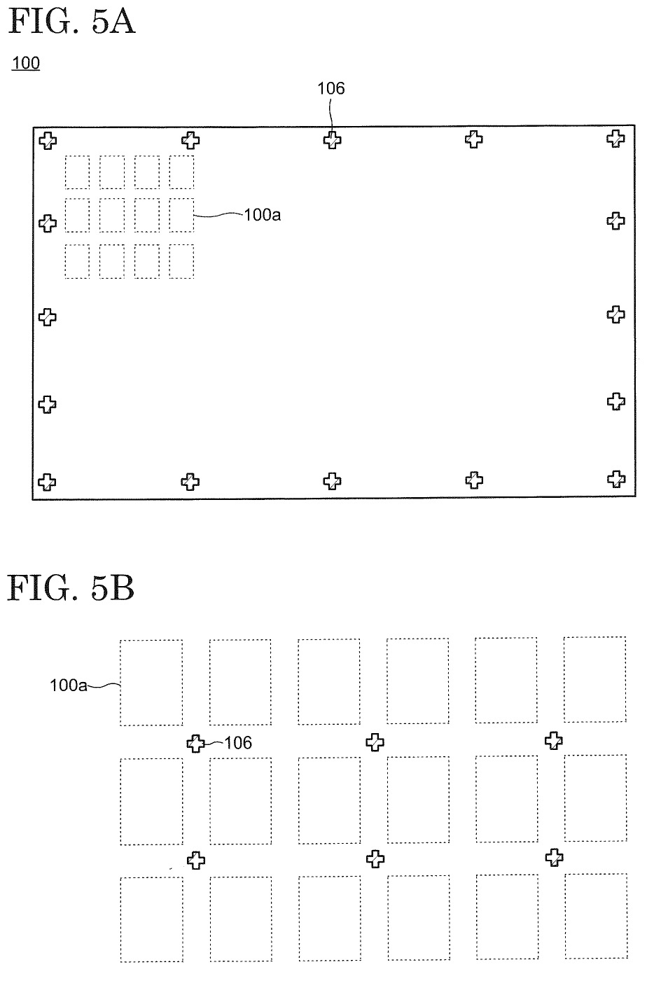

As described below, one or a plurality of detectors is used in this inspecting method, and the inspection is performed while moving the substrate 100 and the detectors relatively to each other. Hence, an alignment mark 106 is formed over the substrate 100 to adjust the position of the detectors (alignment). For example, as shown in FIG. 5A, a plurality of alignment marks 106 is formed outside the region surrounding all of the region 100a where the light-emitting elements 110 are to be formed (element-fabrication region). As shown in FIG. 5B, the alignment marks 106 may be formed within the element-fabrication region. In this case, the alignment marks 106 are formed between the regions 100a adjacent in the row direction, the column direction, or the diagonal direction to the row direction and the column direction.

As described below, in this inspecting method, the plurality of light-emitting elements 110 or the plurality of semiconductor layers is divided into a plurality of element groups each containing a plurality of light-emitting elements 110 or a plurality of semiconductor layers, and inspection is performed with the detectors for each element group. Hence, the alignment marks 106 are arranged so that at least two alignment marks 106 appear in the field of vision of each detector (i.e., the measurement region of each detector). Specifically, the plurality of light-emitting elements 110 or the plurality of semiconductor layers is divided into the plurality of element groups so that one element group contains a plurality of light-emitting elements 110 or semiconductor layers arranged in a matrix shape with n rows and m columns. Accordingly, the alignment marks 106 are arranged so that there are at least two alignment marks 106 in the region including the light-emitting elements 110 or the semiconductor layers arranged in a matrix shape with n consecutive rows and m consecutive columns. Here, m and n are each an integer and may be independently selected from a range equal to or larger than 3 and equal to or smaller than 20 or equal to or larger than 5 and equal to or smaller than 10, for example. The alignment marks 106 may be used for the etching process of the semiconductor layers.

The shape and size of the alignment mark 106 may be determined arbitrarily. The alignment mark 106 may be formed with a sputtering method using a material contained in the semiconductor layer such as a gallium nitride-based material, for example, by which not only can the alignment mark 106 be formed using the equipment used to form the semiconductor layers, but also the alignment mark 106 can be prevented from being damaged by heat during the semiconductor layer fabrication. Alternatively, the alignment mark 106 may be formed as a metal film. For example, the alignment mark 106 may be formed to include a material having a melting point higher than the temperature at the time of semiconductor layer fabrication, in addition to the materials usable for the anode 118 or the cathode 120. Specifically, in addition to gold and palladium, a metal such as molybdenum, tungsten, tantalum, copper, and titanium may be used to form the alignment marks 106. When a metal is used, the alignment marks 106 may be formed with a CVD method or a sputtering method.

Alternatively, a glass substrate may be used as the substrate 100, and the surface of the glass substrate may be processed to form the alignment marks 106. For example, the alignment mark 106 may be formed by sandblasting, hydrofluoric acid treatment, or irradiation of the substrate 100 with a laser such as a carbon dioxide laser.

### (2) Formation of Barrier Layer and Buffer Layer

The barrier layer 102 and the buffer layer 104 are formed over the substrate 100 to be shared by the plurality of light-emitting elements 110 or the plurality of semiconductor layers (see FIG. 4B). The barrier layer 102 can be formed by a CVD method, a sputtering method, or the like.

The buffer layer 104 may also be formed using a CVD method or a sputtering method. In order to more effectively grow the semiconductor layer in the c-axis direction, it is preferable to form the buffer layer 104 so that the surface flatness thereof is high. Specifically, the arithmetic mean roughness (Ra) of the surface of the buffer layer 104 is preferred to be smaller than 2.3 nm. The root mean square roughness (Rq) of the surface of the buffer layer 104 is preferred to be smaller than 2.9 nm. In order to obtain high surface flatness, the buffer layer 104 is preferably formed so that the thickness is equal to or less than 50 nm, and the buffer layer 104 is formed with a thickness of equal to or more than 10 nm and equal to or less than 50 nm, for example.

### (3) Formation of Semiconductor Layer and Electrode

Next, the n-type cladding layer 112, the emission layer 114, and the p-type cladding layer 116 structuring the semiconductor layer are sequentially formed (see FIG. 4B). Each of these layers can be formed utilizing a sputtering method. For example, the substrate 100 and a gallium nitride target are placed in a chamber of a sputtering apparatus. The gallium nitride target is preferred to have an atomic ratio of gallium to nitrogen of equal to or higher than 0.7 and equal to or lower than 2. After exhausting the chamber sufficiently, a sputtering gas is supplied. Rare gases such as argon and krypton are exemplified as the sputtering gas. The substrate 100 is heated at a temperature from room temperature to less than 600° C., preferably equal to or higher than 100° C. and equal to or lower than 400° C. Thus, a substrate containing amorphous glass can be used as the substrate 100 supporting the light-emitting elements 110. Furthermore, a voltage is applied between the substrate 100 and the gallium nitride target to generate plasma, by which the sputtering gas is ionized. The ionized sputtering gas is accelerated and collides with the target, and the material scattered by this impact is deposited over the substrate 100, forming a functional layer containing gallium nitride. A gallium nitride target containing silicon or germanium or a gallium nitride target containing magnesium may be used instead of the gallium nitride target, by which the n-type cladding layer 112 or the p-type cladding layer 116 respectively imparted with n-type or p-type conductivity can be formed. Moreover, the use of an indium gallium nitride target and a gallium nitride target allows the formation of the emission layer 114 in which indium gallium nitride films and gallium nitride films are alternately stacked.

As mentioned above, the semiconductor layer is formed over the buffer layer 104. Therefore, even if the vapor phase epitaxial growth conventionally used to form a semiconductor layer is not applied, the semiconductor particles ejected by sputtering the semiconductor target are c-axis oriented by the buffer layer 104 as they are deposited to form the semiconductor layer. As a result, the semiconductor layer with high crystallinity can be constructed without high temperatures during the semiconductor layer formation. Since the patterning of the semiconductor layer can be performed by applying known photolithography, a detailed description is omitted.

The anode 118 and the cathode 120 may be formed using an evaporation method, a CVD method, or a sputtering method (see FIG. 4B)

### (4) Inspecting Method Using Photoluminescence

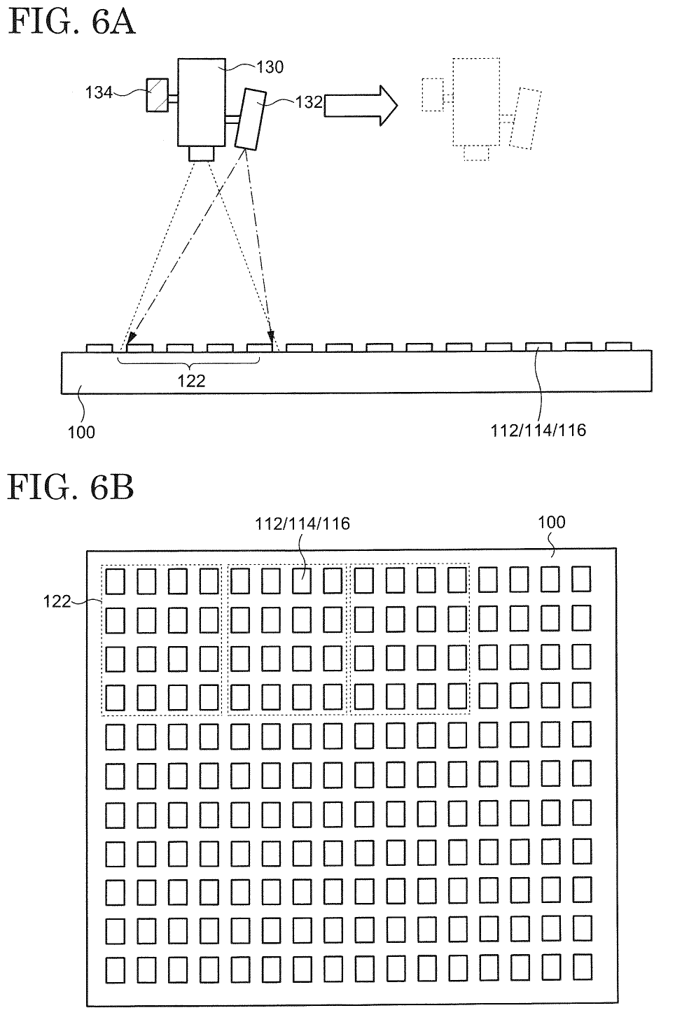

When using photoluminescence in this inspecting method, the semiconductor layer is subjected to inspection before the anode 118 and cathode 120 are formed. Schematic side and top views illustrating the inspection using photoluminescence are respectively shown in FIG. 6A and FIG. 6B. In these drawings, a state is schematically illustrated where up to the p-type cladding layer 116 is formed, but the anode 118 and the cathode 120 are not formed.

As described above, since the light-emitting elements 110, the target of this inspecting method, can be fabricated over the large substrate 100, it is difficult to evaluate photoluminescence properties from individual semiconductor layers in detail if the inspection is conducted so that all of the semiconductor layers are included in the measurement region of the detector. Therefore, in this inspecting method, the semiconductor layers each including the n-type cladding layer 112, the emission layer 114, and the p-type cladding layer 116 are divided into a plurality of element groups 122 as shown in FIG. 6B, and the inspection is performed for each element group 122. Although there is no restriction on the number of semiconductor layers included in one element group 122, each element group 122 is set to include a plurality of semiconductor layers arranged in a matrix shape with a plurality of rows and a plurality of columns as described above. The number of rows and columns may be each selected from a range equal to or larger than 3 and equal to or smaller than 20 or equal to or larger than 5 and equal to or smaller than 10. In the example shown in FIG. 6B, each element group 122 includes 16 semiconductor layers arranged in a matrix shape with 4 rows and 4 columns.

In this inspecting method, a light source 132 for irradiating the semiconductor layers with light as well as the detector 130 configured to acquire emission properties from the semiconductor layers are used. The detector 130 can also be used in the inspecting method using electroluminescence as described below. Thus, the detector 130 may be a spectrophotometer configured to split the light emitted from the semiconductor layer to generate a spectrum, for example. Alternatively, the detector 130 may be a luminance meter configured to measure the luminance and/or chromaticity of the emission from the semiconductor layer. Alternatively, the detector 130 may be an image-capturing device capable of imaging each semiconductor layer. The shape and the area of the emission region in each semiconductor layer can be measured using an image-capturing device. Alternatively, the detector 130 may have two or more of the functions of a spectrophotometer, a luminance meter, and an image-capturing device, or may be configured by combining two or more of a spectrophotometer, a luminance meter, and an image-capturing device. The detector 130 is arranged using the alignment marks 106 so that it can detect the emission from the plurality of semiconductor layers included in one element group 122, and its measurement region is adjusted (see the dotted lines in FIG. 6A).

The light source 132 is configured to emit light which can be absorbed by the semiconductor layer, particularly the emission layer 114 (see the chain arrows in FIG. 6A), and light in the wavelength region of 300 nm to 350 nm is used, for example. The light may be non-coherent light or laser light such as laser light of a He—Cd laser. The light source 132 may be configured to simultaneously irradiate all or a plurality of semiconductor layers included in one element group 122 or may be configured to sequentially irradiate individual semiconductor layers.

Although the detector 130 and the light source 132 are connected to each other in the example shown in FIG. 6A, these components may not be connected to each other and may be separated. Since the inspection is performed on each element group 122, a movement mechanism (not illustrated) is provided to move the detector 130 and the substrate 100 relatively to each other in a direction parallel to the top surface of the substrate 100, as indicated by the white arrow in FIG. 6A. The moving mechanism may be, for example, a conveyor or a robot for moving the substrate 100 or a rail or a robot for moving the detector 130. The position of the detector 130 is adjusted using the alignment marks 106 formed over the substrate 100. A terminal which is not illustrated is connected wirelessly or wired to the detector 130 to receive the photoluminescence properties obtained by the detector 130 as data and to process and store the data.

As mentioned above, the n-type cladding layer 112, the emission layer 114, and the p-type cladding layer 116 structuring the semiconductor layers are formed by a sputtering method, and the temperature during deposition may range from 500° C. to 600° C. On the other hand, since a strain point of a glass substrate exemplified as the substrate 100 is 650° C. to 720° C., the semiconductor layers can be formed at a temperature lower than the strain point of the substrate 100. However, when the temperature at the time when the semiconductor layer is formed approaches the strain point, deformation of the substrate 100 including warping or bending of the substrate 100 may occur. When such deformation occurs, the distance between the semiconductor layer and the detector 130 may change, or the emission direction of the light from the semiconductor layer may change. Therefore, a rangefinder 134 may be used to measure the distance of the detector 130 from the substrate 100 and/or the angle of the detector 130 with respect to the substrate 100 in order to compensate for the influence of the deformation of the substrate 100. As a rangefinder 134, a laser rangefinder is exemplified which is capable of irradiating an object with laser light and measuring a distance and an angle on the basis of the reflected light. The rangefinder 134 is preferably fixed to the detector 130. The detector 130 may be configured so that its position and angle with respect to the substrate 100 can be adjusted according to the distance of the detector 130 from the substrate 100 and/or the angle of the detector 130 with respect to the substrate 100 obtained by the rangefinder 134. With this structure, the photoluminescence properties can be accurately evaluated even if the substrate 100 is deformed.

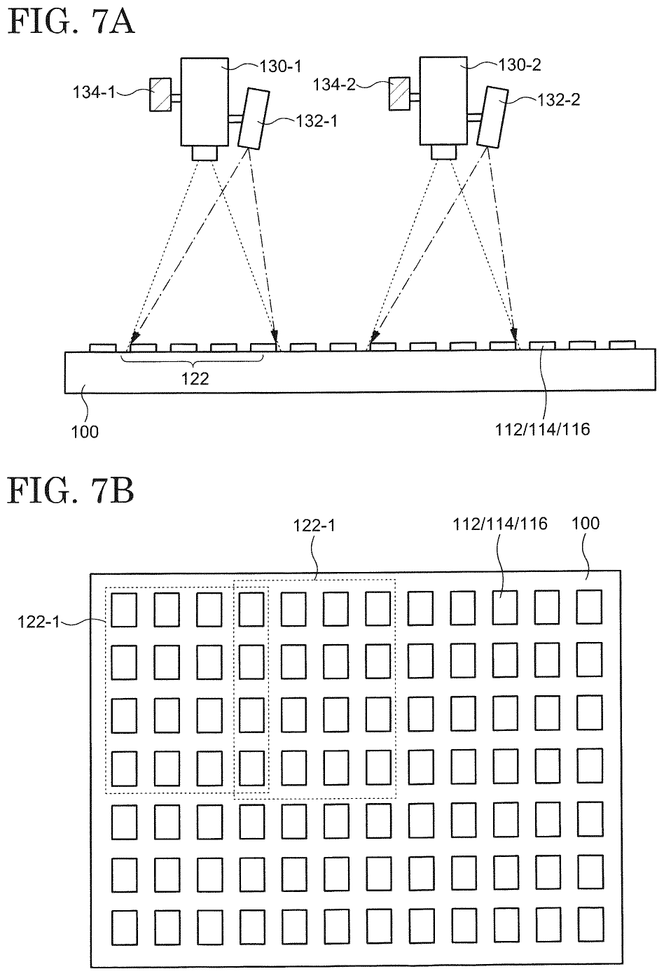

In this inspecting method, a plurality of detectors 130 may be used by which a more efficient inspection can be performed. For example, as shown in the schematic side and top views of FIG. 7A and FIG. 7B, a first detector 130-1 and a second detector 130-2 may be used to acquire the photoluminescence properties of the plurality of semiconductor layers included in the element group 122. In this case, a first light source 132-1 and a second light source 132-2 as well as a first rangefinder 134-1 and a second rangefinder 134-2 respectively coordinated with the first detector 130-1 and the second detectors 130-2 may be used.

When the plurality of detectors 130 is used, the photoluminescence properties obtained from the same semiconductor layer are acquired by the plurality of detectors 130 in order to eliminate variations in detection sensitivity between the detectors 130. Specifically, as shown in FIG. 7B, the semiconductor layers are divided into the plurality of element groups 122 so that at least one light-emitting element is included in both two adjacent element groups 122-1 and 122-2. The number of light-emitting elements 110 shared by the two element groups 122-1 and 122-2 is one or more. The photoluminescence properties of the shared light-emitting elements 110 are measured using the plurality of detectors 130, and the obtained data or the detectors 130 may be calibrated so that both results are identical. Such calibration eliminates the necessity to evaluate the same element group 122 with the plurality of detectors 130, enabling a highly efficient inspection.

In this inspecting method, the light source 132 is used to irradiate the semiconductor layers of each element group 122, and the emission of the semiconductor layers is measured with the detector 130 to evaluate the photoluminescence properties. In the evaluation, characteristics such as the emission peak wavelength and its intensity, the shape of the spectrum, and the rising and falling wavelengths of the spectrum are used, for example. Alternatively, characteristics such as the luminance and chromaticity of the emission from each semiconductor layer or the shape and area of the emission region are evaluated. If these characteristics match pre-determined specs, the semiconductor layer is judged to be a good product, otherwise, the semiconductor layer is judged to be a defective product. Each semiconductor layer may also be classified (ranked) on the basis of these characteristics.

### (5) Inspecting Method Using Electroluminescence

When the electroluminescence is utilized in this inspecting method, the light-emitting element 110 obtained after forming the anode 118 and the cathode 120 is subjected to the inspection. Similar to the inspection utilizing the photoluminescence, the electroluminescence properties are acquired and evaluated for each element group 122 in the inspection utilizing electroluminescence. The element group 122 for the inspection utilizing the electroluminescence may be the same as or different from the element group 122 for the inspection utilizing the photoluminescence. Specifically, all of the light-emitting elements 110 included in one element group 122 in the inspection utilizing the electroluminescence may be the light-emitting elements 110 included in one element group 122 in the inspection utilizing the photoluminescence. Alternatively, only a part of the light-emitting elements 110 included in one element group 122 in the inspection utilizing the electroluminescence may be included in one element group 122 in the inspection utilizing the photoluminescence. Hereinafter, the inspecting method utilizing the electroluminescence is described in detail below, and the explanation for the structures and the methods similar to the inspecting method utilizing the photoluminescence may be omitted.

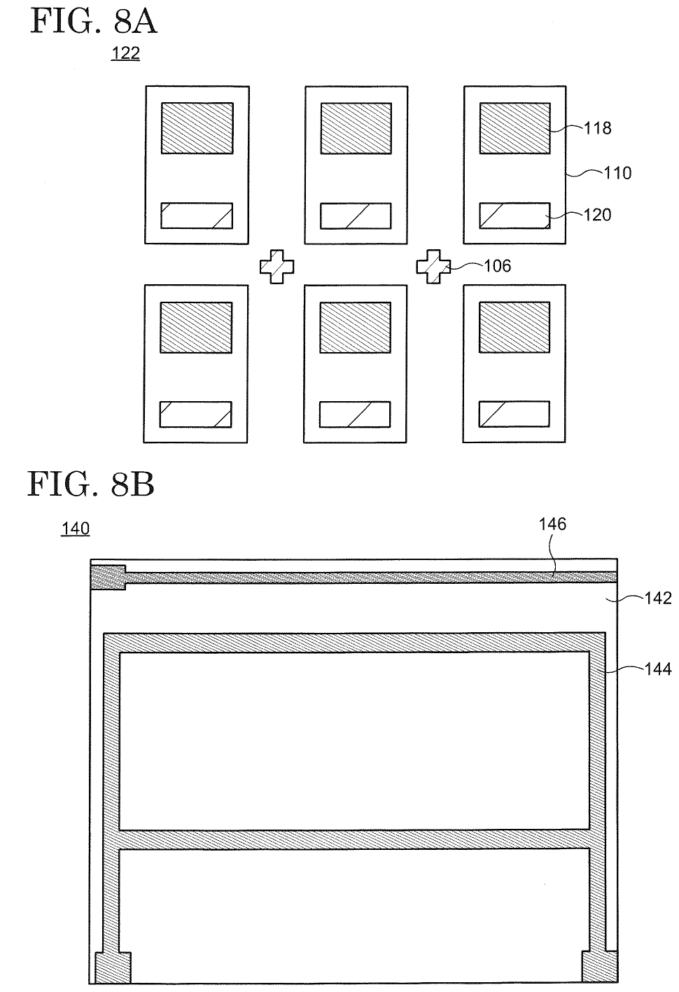

In the inspection utilizing the electroluminescence, electric power is supplied to the plurality of light-emitting elements 110 included in each element group 122, and the emission generated in the emission layer 114, i.e., the electroluminescence, is measured with the detector 130 to evaluate the electroluminescence properties. Hence, an inspection substrate is used to supply electric power to each element group 122. A schematic top view of one element group 122 and a schematic top view of the inspection substrate 140 are respectively shown in FIG. 8A and FIG. 8B. Here, an example is illustrated where six light-emitting elements 110 arranged in two rows and three columns are included in one element group 122. As shown in FIG. 8B, the inspection substrate 140 has a light-transmitting substrate 142 transmitting visible light, an anode wiring 144 and a cathode wiring 146 formed over the light-transmitting substrate 142. Although not illustrated, the inspection substrate 140 may further have alignment marks for aligning the inspection substrate 140. The inspection substrate 140 can be readily and accurately placed over the element group 122 by matching the alignment marks of the inspection substrate 140 with the alignment marks 106 formed over the substrate 100.

The light-transmitting substrate 142 is a glass substrate, for example, and is sized and shaped to cover the entirety of one element group 122 or all of the light-emitting elements 110 included in one element group 122. Since the light-emitting elements 110 included in one element group 122 are also arranged in a matrix shape, the light-transmitting substrate 142 is, for example, square. The anode wiring 144 and the cathode wiring 146 are wirings including a metal such as aluminum, molybdenum, tantalum, titanium, and tungsten, for example, and are arranged to receive electric power from an external power source which is not illustrated.

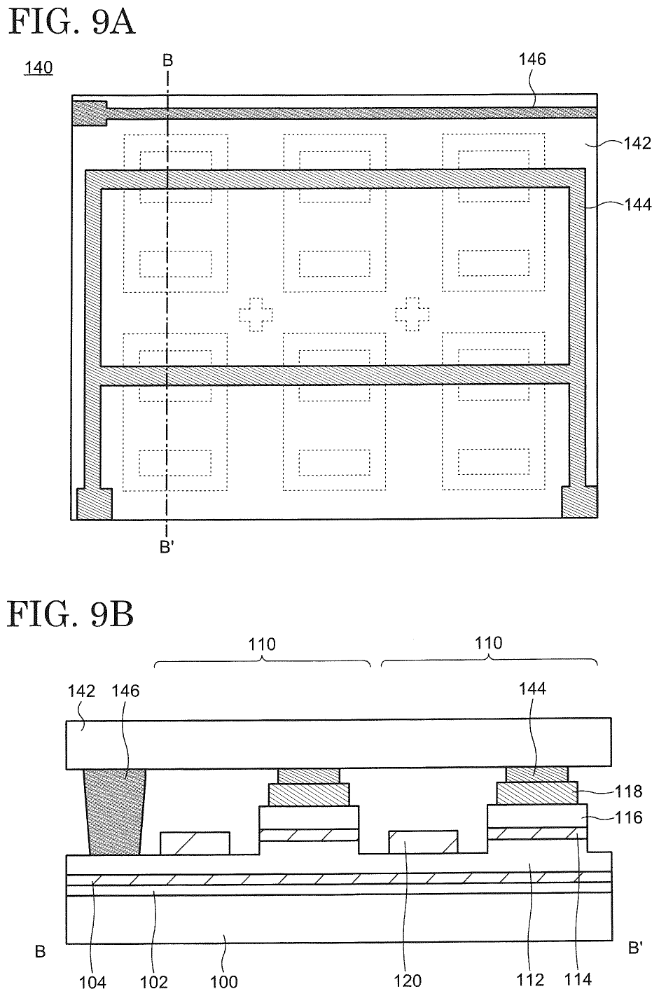

A schematic top view of the state in which the light-transmitting substrate 142 is placed over the element group 122 so that the anode wiring 144 and the cathode wiring 146 are sandwiched between the light-transmitting substrate 142 and the substrate 100 is shown in FIG. 9A, and a schematic view of a cross section along the chain line B-B′ in FIG. 9A is shown in FIG. 9B. As can be understood from these drawings, the cathode wiring 146 is provided so as to be in physical and electrical contact with the n-type cladding layer 112 when the inspection substrate 140 is placed over the light-emitting elements 110. Preferably, the cathode wiring 146 is provided so as to overlap, in the column direction, all of the plurality of light-emitting elements 110 arranged in the row direction in the element group 122 or overlap, in the row direction, all of the plurality of light-emitting elements 110 arranged in the column direction in the element group 122. This arrangement enables a reliable electrical connection between the cathode wiring 146 and the n-type cladding layer 112 and prevents an increase or non-uniformity in the distance from the contact interface between the cathode wiring 146 and the n-type cladding layer 112 to the light-emitting elements 110, which allows the same or substantially the same potential to be supplied to the n-type cladding layer 112 of the plurality of light-emitting elements 110. Meanwhile, the anode wiring 144 is provided to physically and electrically contact all of or at least two of the plurality of light-emitting elements 110 included in the element group 122 simultaneously when the inspection substrate 140 is placed over the light-emitting elements 110. Accordingly, as shown in FIG. 9B, the thicknesses of the anode wiring 144 and the cathode wiring 146 may be different, and the difference therebetween is the difference in height between the top surface of the anode 118 and the top surface of the n-type cladding layer 112 between the light-emitting elements 110.

The inspection substrate 140 having the above structure is arranged so that the anode wiring 144 and the cathode wiring 146 respectively contact the anode 118 and n-type cladding layer 112, and a potential difference is provided therebetween so that the anode wiring 144 has a higher potential than the cathode wiring 146. Then, since the n-type cladding layer 112 is shared by the plurality of light-emitting elements 110, electrons are supplied to the light-emitting elements 110 in the element group 122. On the other hand, holes are supplied to the anodes 118 of the light-emitting elements 110. As a result, the electrons and holes recombine in the emission layer 114, leading to the electroluminescence.

As described above, the anode wiring 144 is provided so as to be electrically connected to the anodes 118 of all of or at least two of the light-emitting elements 110 in the element group 122. Therefore, emission can be simultaneously obtained from all of or at least two of the light-emitting elements 110 in the element group 122 by providing a potential difference between the anode wiring 144 and the cathode wiring 146. In this state, the electroluminescence properties can be acquired using the detector 130 in the same manner as in the inspecting method using the photoluminescence. Note that the detector 130 may be placed on the inspection substrate 140 side, and the light emitted from the emission layer 114 to the anode 118 side may be utilized. Alternatively, the detector 130 may be placed on the substrate 100 side, and the light emitted from the emission layer 114 to the substrate 100 side may be utilized.

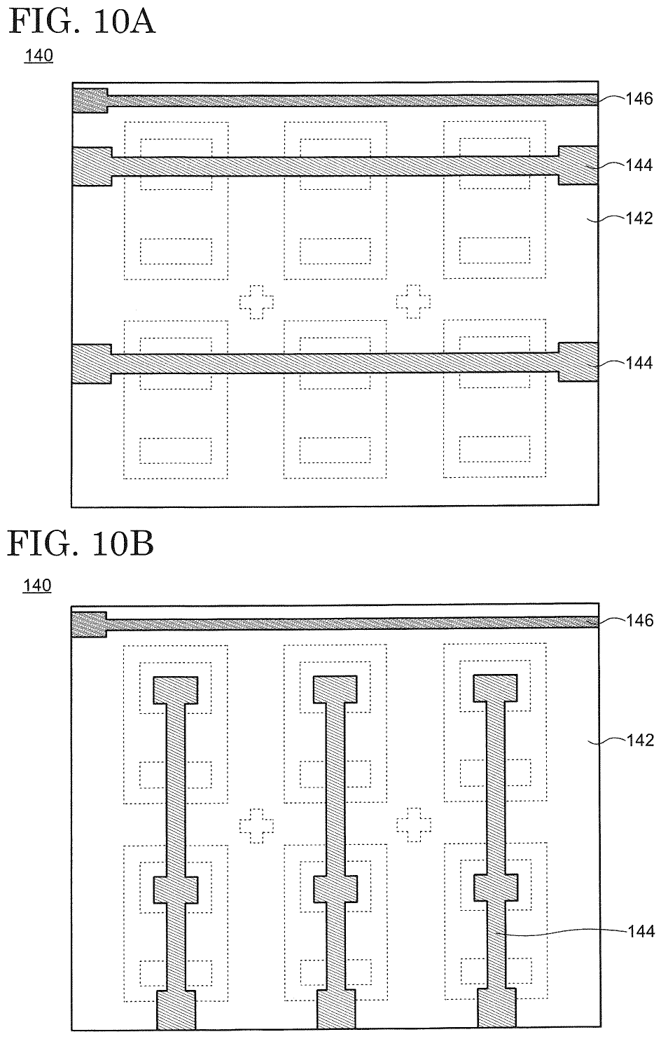

The structure of the inspection substrate 140 is not limited to the above structure. For example, as shown in FIG. 10A and FIG. 10B, the inspection substrate 140 may be configured so that a plurality of anode wirings 144 is provided to supply electric power to the plurality of light-emitting elements 110 for each row or each column. In the example shown in FIG. 10A, the plurality of anode wirings 144 is provided to simultaneously supply electric power to two or more light-emitting elements 110 arranged in each row. On the other hand, in the example shown in FIG. 10B, the plurality of anode wirings 144 is provided to simultaneously supply electric power to the light-emitting elements 110 arranged in each column.

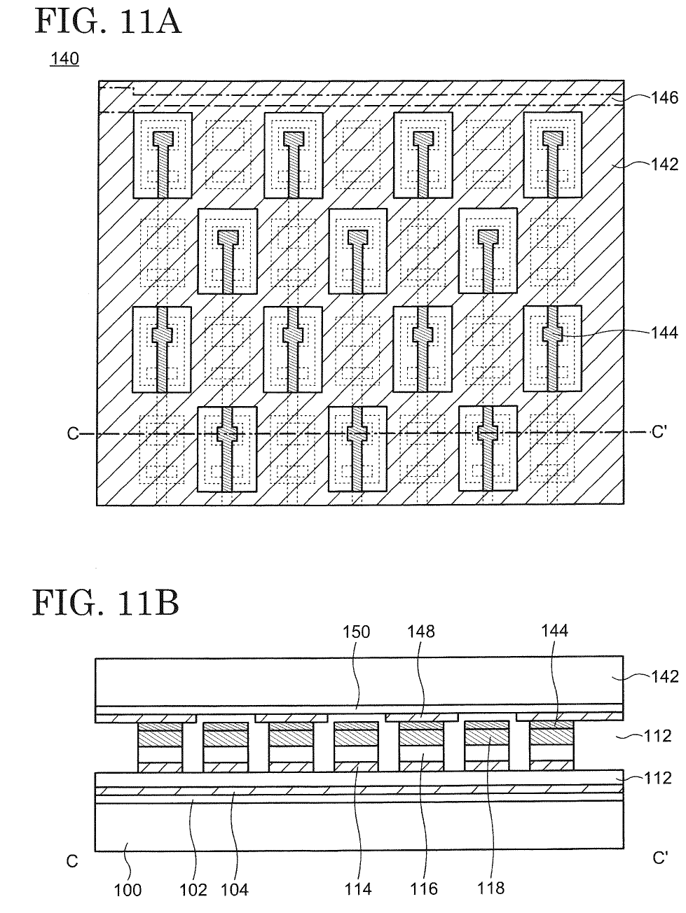

Moreover, as shown in the schematic top view of FIG. 11A and the schematic view of a cross section along the chain line C-C′ thereof (FIG. 11B), a light-shielding film 148 may be provided to the inspection substrate 140 in order to shield the emission from a part of the light-emitting elements 110. The light-shielding film 148 is provided to the light-transmitting substrate 142 either in contact with the light-transmitting substrate 142 or through an undercoat 150. The undercoat 150 is an insulating film and may be composed of one or a plurality of films containing, for example, a silicon-containing inorganic compound. The light-shielding film 148 may include, for example, a metal film with low translucency such as chromium or a resin in which a black or similarly colored pigment is dispersed. Note that the light-shielding film 148 may be provided on the top surface or the bottom surface of the light-transmitting substrate 142.

The light-shielding film 148 has a plurality of openings exposing one or more light-emitting elements 110 when the inspection substrate 140 is placed over the light-emitting elements 110 of the element group 122, shielding the emission from the light-emitting elements 110 overlapping a portion other than the openings (non-opening portion) and allowing the emission from the light-emitting elements 110 overlapping the openings to pass therethrough. The arrangement of the plurality of openings is arbitrary determined, and the openings may be arranged to form a checkerboard pattern, for example. That is, the openings may be provided so as to overlap the light-emitting elements 110 alternately selected in the row direction and/or the column direction. Alternatively, the light-shielding film 148 may be configured to have the openings so that, when the inspection substrate 140 is placed over the light-emitting elements 110 of the element group 122, the openings overlap a pair of light-emitting elements 110 sandwiching one or more light-emitting elements 110, while the non-opening portion overlaps the one or more light-emitting elements 110.

In the case where the light-shielding film 148 is provided, since the anode wirings 144 are formed so that the anodes 108 of all of the light-emitting elements 110 contact any of the anode wirings 144, all of the light-emitting elements 110 contacting the anode wiring 144 simultaneously emit light by supplying a potential difference between the anode wiring 144 and cathode wiring 146. Therefore, in the case where the light-shielding film 148 is not provided, the electroluminescence properties of one light-emitting element 110 may be affected by the electroluminescence of adjacent light-emitting elements 110 when evaluating the electroluminescence properties of the one light-emitting element 110. However, the electroluminescence properties of the light-emitting element 110 overlapping the opening can be obtained while eliminating the influence of the emission from the light-emitting elements 110 overlapping the non-opening portion by providing the light-shielding film 148. Thus, the influence of the electroluminescence from adjacent light-emitting elements 110 can be eliminated by forming the openings in a checkerboard pattern, for example, enabling more accurate evaluation of the electroluminescence properties.

Although a detailed explanation is omitted, the distance of the detector 130 from the substrate and its angle with respect to the substrate may be adjusted in the inspecting method utilizing the electroluminescence similar to the inspecting method utilizing the photoluminescence. In addition, a plurality of detectors 130 may be used for calibration to eliminate detection variations between the detectors 130.

Although a detailed explanation is omitted, the distance of the detector 130 from the substrate and its angle to the substrate may be adjusted in the inspecting method utilizing the electroluminescence similar to the inspection utilizing the photoluminescence. In addition, the plurality of detectors 130 may be used and calibrated to eliminate detection variations between the detectors 130.

As described above, in this inspecting method, the plurality of light-emitting elements 110 provided over the substrate 100, which is an amorphous substrate, is inspected utilizing the photoluminescence and/or the electroluminescence. Although the light-emitting elements 110 are LEDs, the semiconductor layers in the light-emitting elements 110 are formed by applying a sputtering method. Therefore, a large substrate 100, also known as mother glass, can be used. When such a large substrate is used as the substrate 100, a large inspection apparatus is required to inspect the light-emitting elements 110. However, in the present inspecting method, all of the light-emitting elements 110 are divided into the plurality of element groups 122, and the inspection is performed for each element group 122. Therefore, a large-sized detector is not necessary. In addition, since the light-emitting elements 110 over the large substrate 100 can be inspected using the plurality of detectors 130 while eliminating variations in detection sensitivity, the inspection can be performed efficiently and quickly in a short time. These features contribute to a reduction in manufacturing cost of light-emitting devices including the light-emitting elements 110.

Once subjected to this inspecting method, the light-emitting elements 110 over the substrate 100 can be transferred onto a device substrate over which wirings and circuits for driving the light-emitting elements 110 are provided using the so-called transfer method. Thus, a light-emitting device including the light-emitting elements 110 can be manufactured. At this time, since only the light-emitting elements 110 judged as a good product by this inspecting method can be selectively used for manufacturing the light-emitting device, a decrease in the manufacturing yield of the light-emitting device caused by the semiconductor layers or the light-emitting elements 110 can be prevented. Therefore, it is also possible to reduce the manufacturing cost of light-emitting devices such as display devices and lighting devices by applying the embodiment of the present invention.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A method for inspecting a light-emitting element, the method comprising:
forming a buffer layer over an amorphous substrate;
forming, over the buffer layer, an n-type cladding layer, an emission layer, and a p-type cladding layer each including an inorganic semiconductor to form a plurality of semiconductor layers arranged in a matrix form having a plurality of rows and a plurality of columns;
forming an anode and a cathode over each of the plurality of semiconductor layers to form a plurality of light-emitting elements; and
acquiring at least one of a photoluminescence property or an electroluminescence property of the plurality of light-emitting elements using a first detector and a second detector,
wherein the buffer layer has a function to promote crystallization of the semiconductor layers,
the photoluminescence property is acquired before forming the anode and the cathode, and
the electroluminescence property is acquired after forming the anode and the cathode.

2. The method according to claim 1,
wherein the acquisition of the photoluminescence property comprises:
irradiating a first element group including two or more light-emitting elements selected from the plurality of light-emitting elements with light and measuring photoluminescence of the light-emitting elements included in the first element group with the first detector; and
irradiating a second element group including two or more light-emitting elements selected from the plurality of light-emitting elements with light and measuring photoluminescence of the light-emitting elements included in the second element group with the second detector, and
the acquisition of the electroluminescence property comprises:
supplying electric power to a third element group including two or more light-emitting elements selected from the plurality of light-emitting elements and measuring electroluminescence of the light-emitting elements included in the third element group with the first detector, and
supplying electric power to a fourth element group including two or more light-emitting elements selected from the plurality of light-emitting elements and measuring electroluminescence of the light-emitting elements included in the fourth element group with the second detector.

3. The method according to claim 1,
wherein both the photoluminescence property and the electroluminescence property are acquired.

4. The method according to claim 2,
wherein at least one light-emitting element among the plurality of light-emitting elements is included in both the first element group and the second element group, and
the method further comprises calibrating the first detector and the second detector using the photoluminescence of the at least one light-emitting element.

5. The method according to claim 2,
wherein at least one light-emitting element among the plurality of light-emitting elements is included in both the third element group and the fourth element group, and
the method further comprises calibrating the first detector and the second detector using the electroluminescence of the at least one light-emitting element.

6. The method according to claim 2,
wherein the light-emitting elements included in the first element group are the light-emitting elements included in the third element group, and
the light-emitting elements included in the second element group are the light-emitting elements included in the fourth element group.

7. The method according to claim 1, further comprising:
forming, over the amorphous substrate, a plurality of alignment marks for alignment of the first detector and the second detector,
wherein the plurality of alignment marks includes the inorganic semiconductor.

8. The method according to claim 7,
wherein the plurality of alignment marks is formed outside a region in which the plurality of light-emitting elements is arranged.

9. The method according to claim 7,
wherein at least one of the plurality of alignment marks is formed between adjacent light-emitting elements.

10. The method according to claim 1,
wherein the first detector and the second detector are configured so that a distance from the amorphous substrate and/or an angle with respect to the amorphous substrate can be adjusted.

11. The method according to claim 1,
wherein the acquisition of the electroluminescence property comprises supplying electric power to the plurality of light-emitting elements through an inspection substrate,
the inspection substrate comprises:
a light-transmitting substrate transmitting visible light;
a first wiring over the light-transmitting substrate; and
a second wiring over the light-transmitting substrate,
the first wiring is configured so as to be electrically connected to the n-type cladding layer when the inspection substrate is arranged over the plurality of light-emitting elements, and
the second wiring is configured so as to be electrically connected to the anodes of at least two light-emitting elements when the inspection substrate is arranged over the plurality of light-emitting elements.

12. The method according to claim 1,
wherein the n-type cladding layer continues between adjacent light-emitting elements.

13. The method according to claim 11,
wherein the at least two light-emitting elements are arranged in a direction of the row or the column.

14. The method according to claim 11,
wherein the at least two light-emitting elements are arranged so as to sandwich another light-emitting element,
the inspection substrate further comprises a light-shielding film, and
the light-shielding film is configured to overlap the other light-emitting element when the inspection substrate is arranged over the plurality of light-emitting elements.
